(19) United States
(12) Patent Application Publication
(10) Pub. No.: US 2015/0271952 A1
(43) Pub. Date: Sep. 24, 2015

(54) POWER SUPPLY UNIT WITH DUST-REMOVING APPARATUS

(71) Applicant: HON HAI PRECISION INDUSTRY CO., LTD., New Taipei (TW)

(72) Inventor: Te-Ming CHANG, New Taipei (TW)

(21) Appl. No.: 14/471,757

(22) Filed: Aug. 28, 2014

(30) Foreign Application Priority Data
Mar. 19, 2014 (TW) 103110310

(51) Int. Cl. H05K 7/20; B01D 46/00; B01D 46/10

(52) U.S. Cl. CPC H05K 7/20181; H05K 7/20909; H05K 7/20145; B01D 46/10; B01D 46/0067; B01D 46/0005

(57) ABSTRACT

A power supply unit includes a housing, a dust-removing apparatus and a fan. The housing includes a rear panel and a top panel. The rear panel defines an air inlet. The fan is mounted to an outer side of the rear panel and aligned with the air inlet. The dust-removing apparatus includes a bracket and a filter. The bracket includes two support plates perpendicularly mounted on an inner side of the rear panel, and the supporting plates are located at two opposite ends of the air inlet. The support plates define a positioning groove parallel to the rear panel. The top panel defines an opening aligned with the positioning groove. The filter can be inserted into the positioning groove through the opening. The filter can be detached from the housing through the opening.

### FIELD

The present disclosure relates to a power supply unit.

### BACKGROUND

Usually, heat is removed by a fan from the power supply unit. However, dust will enter the power supply unit through the fan, which results in unstable working performance of the power supply unit. In order to prevent the dust from entering the power supply unit, a filter may be installed opposite to the air outlets of the fan with screws. However, the filter needs to be taken out to clean the dust thereon, and installation or removal of the screws is time consuming and troublesome.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a power supply unit.

FIG. 2 is a partial assembled, isometric view of the power supply unit of FIG. 1.

FIG. 3 is an assembled, isometric view of the power supply unit of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

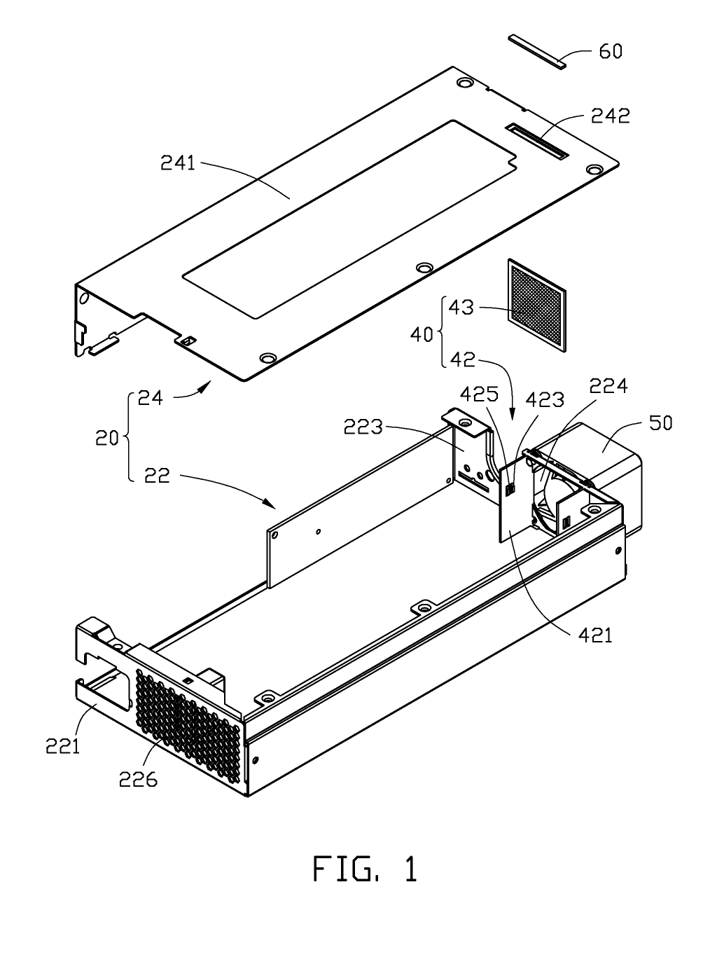

FIG. 1 illustrates an exemplary embodiment of a power supply unit. The power supply unit can comprise a housing 20, a dust-removing apparatus 40, a fan 50, and a rubber stopper 60.

A power supply can be installed in the housing 20 of the power supply unit. The housing 20 can comprise a lower housing 22 and an upper housing 24. The lower housing 22 can comprise a front panel 221 and a rear panel 223 opposite to the front panel 221. The rear panel 223 defines an air inlet 224 and the fan 50 opposite to the air inlet 224 is mounted on the outside of rear panel 223. The front panel 221 defines a plurality of air outlets 226 opposite to the air inlet 224. The upper housing 24 can comprise a top panel 241, and the top panel 241 defines an opening 242 in the back-end.

The dust-removing apparatus 40 can comprise a bracket 42 and a filter 43. The bracket 42 can comprise two support plates 421 vertically extending from the inside of the rear panel 223. The two support plates 421 are located at two opposite ends of the air inlet 224. The distance between the two support plates 421 is the same as the length of the opening 242 on the top panel 241. A pair of raised bumps 423 protrude from the inside surface of each support plate 421, and the two raised bumps 423 define a space therebetween. The two pairs of opposite raised bumps 423 cooperatively define a positioning groove 425 parallel with the rear panel 223.

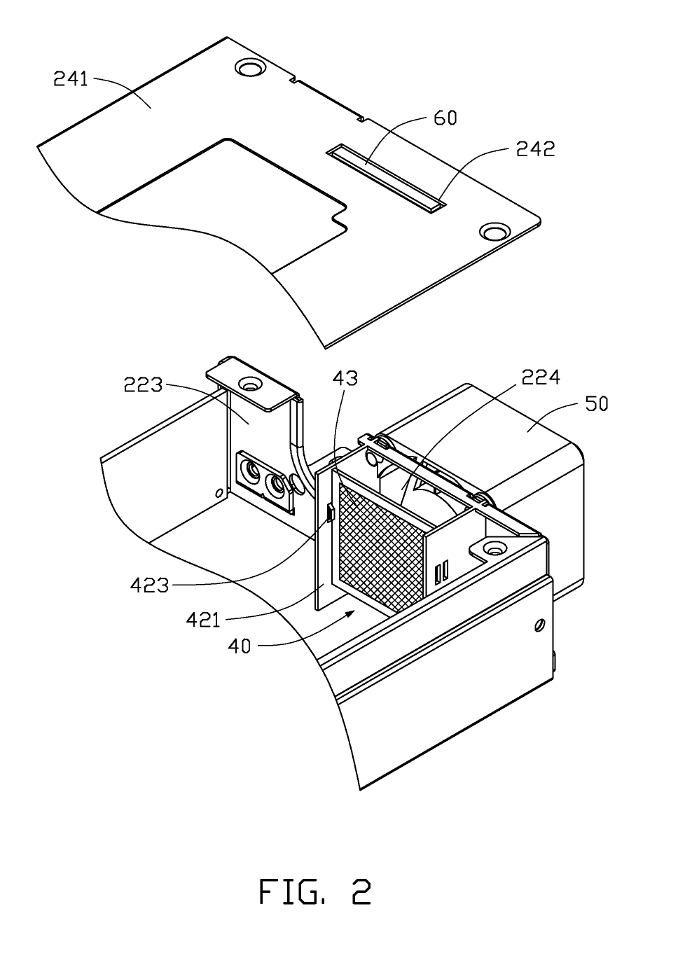

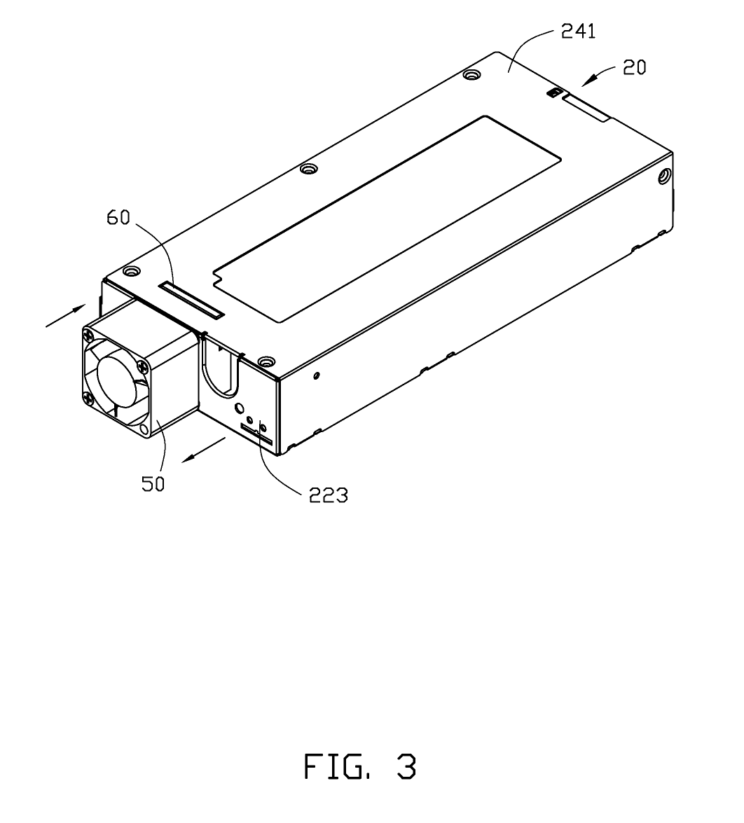

FIG. 2 and FIG. 3 show that in assembly, the upper housing 24 is placed on the lower housing 22, and the opening 242 of upper housing 24 aligns with the positioning groove 425. The filter 43 is inserted into the positioning groove 425 through the opening 242. The top end of the filter 43 is thus received in the opening 242, and the filter 43 faces the air inlet 224. Then the rubber stopper 60 is inserted in and shields the opening 242. Therefore, the filter 43 can prevent the dust from entering the power supply unit.

When cleaning the filter 43 is needed, the rubber stopper 60 is taken out from the opening 242, and then the filter 43 is pulled out from the opening 242.

In the other embodiment of the power supply unit, the fan 50 is set to reverse rotation every once in a while. When the fan 50 has forward rotation, the air flows through the fan 50 and the filter 43, and enters into the power supply unit. Then the heated air is discharged from the air outlets 226. When the fan 50 has reverse rotation, the air in the housing 20 flows through the filter 43, and is discharged from the fan 50. Meanwhile, the dust on the filter 43 is discharged from the fan 50, which prevents dust from accumulating on the filter 43.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A power supply unit, comprising:
a housing comprising a rear panel and a top panel, the rear panel defining an air inlet, a front end of the top panel defining an opening;
a dust-removing apparatus comprising a bracket and a filter, the bracket comprising two support plates vertically extending from an inner side of the rear panel and located at two opposite ends of the air inlet, the two support plates defining a positioning groove parallel with the rear panel and aligned with the opening; and
a fan mounted on an outer side of the rear panel and aligned with the air inlet;
wherein the filter is capable of being inserted into the positioning groove through the opening, and detached from the housing through the opening.

2. The power supply unit of claim 1, wherein a pair of raised bumps protrude on an inner surface of each of the support plates, and the two pairs of opposite raised bumps cooperatively define the positioning groove.

3. The power supply unit of claim 1, wherein the power supply unit comprises a rubber stopper removably received in the opening.

4. The power supply unit of claim 1, wherein a top end of the filter is received in the opening.

5. The power supply unit of claim 1, wherein the housing comprises a front panel, and the front panel defines a plurality of air outlets opposite to the air inlet.

6. The power supply unit of claim 1, wherein the fan has a reverse rotation every once in a while, and when the fan has forward rotation, the air flows through the fan and the filter, enters into the power supply unit, and is discharged from the air outlets; and when the fan has reverse rotation, the air in the housing flows through the filter and is discharged from the fan, and the dust on the filter is discharged from the fan.
